(19) United States
(12) Patent Application Publication
(10) Pub. No.: US 2026/0314275 A1
(43) Pub. Date: Oct. 8, 2026

(54) METHOD FOR MANUFACTURING AN ELECTRODE STRUCTURE FOR AN ION TRAP AND METHOD FOR MANUFACTURING AN ELECTRODE ARRANGEMENT FOR A 3-DIMENSIONAL ION TRAP

(71) Applicant: Fraunhofer-Gesellschaft zur Förderung der angewandten Forschung e.V., München (DE)

(72) Inventors: Christoph KUTTER, München (DE); Peter RAMM, München (DE); Bassem BADAWI, München (DE)

(21) Appl. No.: 18/747,605

(22) Filed: Jun. 19, 2024

(30) Foreign Application Priority Data
Jun. 23, 2023 (DE) 102023205968.1
Jan. 31, 2024 (EP) 24155147.2
Mar. 28, 2024 (EP) 24167488.6

(51) Int. Cl. H10P 10/00; G21K 1/20; H10W 80/00

(52) U.S. Cl. CPC H10P 10/14; G21K 1/20; H10W 80/312

(57) ABSTRACT

A method for manufacturing an electrode structure for an ion trap includes providing a base substrate comprising a patterned metallization arrangement arranged in an insulation material on a semiconductor layer, providing an insulation substrate comprising a dielectric material, connecting a surface region of the base substrate arranged on the insulation material to the insulation substrate by means of a bonding process, and backthinning the base substrate by removing the semiconductor layer to the insulation material of the base substrate, wherein the electrode structure for the ion trap is formed by performing the step of backthinning to the metallization arrangement or by depositing a patterned surface metallization on the insulation material of the back-thinned base substrate, or wherein the electrode structure for the ion trap is formed by the patterned metallization arrangement.

### CROSS-REFERENCE TO RELATED APPLICATIONS

This application claims priority from European Application Number EP24167488.6, which was filed on Mar. 28, 2024, German Application Number 102023205968.1, which was filed on Jun. 23, 2023 and European Patent Application No. 24155147.2, which was filed on Jan. 31, 2024, which are incorporated herein in their entirety by reference.

The present invention relates to methods for manufacturing an electrode structure for an ion trap, in particular to connecting a base substrate to an insulation substrate. The present invention relates to a method for manufacturing an electrode arrangement for a 3-dimensional ion trap.

For example, a method for manufacturing surface ion traps by means of single and/or multilayer metallization on glass, quartz, corundum, diamond or ceramic substrates as well as a structure of a 3-dimensional ion trap arrangement using surface ion traps is presented.

### BACKGROUND OF THE INVENTION

Quantum computers are processors that use quantum mechanical states of systems, such as qubits. One approach for the realization of qubits in quantum computers is the use of ions in ion traps. Here, for example, individual ions are lined up in a row by electromagnetic fields in vacuum.

Modern ion traps, such as those used for quantum computers, comprise, for example, surface electrodes and are controlled by a multilayer metal structure. Such structures are manufactured in standardized process sequences from silicon semiconductor production, as the same are particularly controllable and scalable. In combination with other metallic structures, such as an electrically conductive shielding within a silicon substrate, this can result in large parasitic capacitances that can shorten the coherence time of the ion states.

### SUMMARY

According to an embodiment, a method for manufacturing an electrode structure for an ion trap may have the steps of: providing a base substrate comprising a patterned metallization arrangement arranged in an insulation material on a semiconductor layer, providing an insulation substrate comprising a dielectric material, connecting a surface region of the base substrate arranged on the insulation material to the insulation substrate by means of a bonding process, and backthinning the base substrate by removing the semiconductor layer to the insulation material of the base substrate, wherein the electrode structure for the ion trap is formed by performing the step of backthinning to the metallization arrangement, or by depositing a patterned surface metallization on the insulation material of the back-thinned base substrate, or wherein the electrode structure for the ion trap is formed by the patterned metallization arrangement.

According to another embodiment, a method for manufacturing an electrode arrangement for a 3-dimensional ion trap may have the steps of: performing the above method for manufacturing an electrode structure on a back-thinned base substrate, providing a further substrate with a further electrode structure, connecting the back-thinned base substrate and the further substrate by means of a spacer structure arranged therebetween, so that the electrode structure and the further electrode structure face each other and form the electrode arrangement for the 3-dimensional ion trap.

The present invention is based on the realization that the disclosed manufacturing methods can be used for manufacturing an electrode structure using a base substrate with a semiconductor layer that is accessible to manufacturing by standard semiconductor manufacturing process steps, and that the base substrate can be subjected to backthinning as part of the manufacturing process, which can (partially or completely) remove this semiconductor layer. This can reduce or avoid problems caused by semiconductor materials such as silicon (e.g. high parasitic capacitances). Especially when used for ion traps, this can improve coherence times of qubits. It has been found that connecting to an insulation substrate comprising a dielectric material provides a carrier that provides mechanical stability to the insulation material having the patterned metallization arrangement for processing (e.g. when backthinning and connecting to other components), but does not exhibit the disadvantages described above in connection with the semiconductor layer, or exhibits them to a lesser extent.

Since the base substrate can be manufactured using standard semiconductor manufacturing process steps, the metallization arrangement can also be manufactured using standard semiconductor manufacturing process steps.

Therefore, the metallization arrangement and the resulting electrode structure can be manufactured with high precision and in scalable quantities. A base substrate manufactured using standard semiconductor manufacturing process steps comprises structures that usually exhibit uniform behavior during backthinning, so that a (e.g. flat) shape of a surface of the back-thinned base substrate and the patterned surface metallization deposited thereon can be controlled with high precision.

It was recognized that the advantages of the electrode structures can also be used when connecting electrode structures into an electrode arrangement. The combination of opposing electrode structures increases flexibility in a field distribution so that positions of ions in a three-dimensional space can be better controlled. For example, a 3-dimensional ion trap, e.g. a Paul ion trap arrangement, can be realized by two or more electrode structures (or surface traps comprising such electrode structures). The arrangement of the electrode structures and the electric fields generated by the same can be controlled during manufacturing the electrode structures and by the spacer structure.

Thus, an electrode structure and an electrode arrangement, which are accessible for standard semiconductor manufacturing process steps but reduce problems caused by materials in semiconductor manufacturing, can be manufactured.

### BRIEF DESCRIPTION OF THE DRAWINGS

Embodiments of the present invention will be detailed subsequently referring to the appended drawings, in which:

FIG. 1 shows a schematic flow diagram of the inventive manufacturing process according to an embodiment;

FIG. 2a shows a schematic cross-section of an example of a base substrate having a semiconductor layer and a patterned metallization arrangement arranged in an insulation material;

FIG. 2b shows a schematic cross-section of an example of a base substrate having metal pads;

FIG. 3a shows a schematic cross-section of an example of an insulation substrate with a dielectric material;

FIG. 3b shows a schematic cross-section of an example of an insulation substrate with a metal pad;

FIG. 3c shows a schematic cross-section of an example of an insulation substrate with several metal pads;

FIG. 4a shows a schematic cross-section of a separate arrangement of the base substrate and the insulation substrate;

FIG. 4b shows a schematic cross-section of an arrangement of the base substrate on the insulation substrate;

FIG. 4c shows a schematic cross-section of a bond of the base substrate with the insulation substrate;

FIG. 5a shows a schematic cross-section of an example of a bond of the base substrate with the insulation substrate by means of a metal bonding process;

FIG. 5b shows a schematic cross-section of an example of a bond of the base substrate with the insulation substrate by means of a metal bonding process;

FIG. 6a shows a schematic cross-section of an example in which the electrode structure for the ion trap is formed by performing the step of backthinning to the metallization arrangement;

FIG. 6b shows a schematic cross-section of an example in which the electrode structure for the ion trap is formed by depositing a patterned surface metallization on the insulation material of the back-thinned base substrate;

FIG. 7a shows a schematic cross-section of an example of a base substrate before a recess is formed;

FIG. 7b shows a schematic cross-section of the base substrate of FIG. 7a after a recess has been formed;

FIG. 7c shows a schematic cross-section of a bond after connecting the base substrate of FIG. 7b with an insulation substrate;

FIG. 8a shows a schematic cross-section of an electrode device with the bond of FIG. 7c after backthinning the base substrate;

FIG. 8b shows a schematic cross-section of the electrode device of FIG. 8a after a metallization has been deposited;

FIG. 9a shows a schematic flow diagram of an inventive manufacturing process according to an embodiment;

FIG. 9b shows a schematic cross-section of an example of an electrode system with an electrode arrangement for a 3-dimensional ion trap;

FIG. 10a shows a schematic cross-section of another example of an electrode system with an electrode arrangement for a 3-dimensional ion trap;

FIG. 10b shows a schematic cross-section of a further example of an electrode system 400 for a 3-dimensional ion trap.

FIG. 11a shows a schematic cross-section of another example of an electrode system for a 3-dimensional ion trap;

FIG. 11b shows a schematic cross-section of another example of an electrode system for a 3-dimensional ion trap with a metallization surface on non-metallic sidewall regions; and

FIG. 12 shows a schematic top view of an example of an ion trap with an electrode device.

### DETAILED DESCRIPTION OF THE INVENTION

Before embodiments of the present invention will be explained in more detail below with reference to the drawings, it should be noted that identical, functionally equal or equal elements, objects, functional blocks and/or process steps are provided with the same reference numbers in the different figures, so that the description of these elements, objects, functional blocks and/or process steps (with the same reference numbers) shown in different embodiments is interchangeable or interapplicable.

### DETAILED DESCRIPTION OF THE FIGURES AND EMBODIMENTS

In the following description, the description of a semiconductor layer means that the semiconductor layer comprises a semiconductor material, i.e., is formed at least partially or also completely from the semiconductor material. In the following description, the description of an insulation substrate means that the substrate comprises an electrically insulation material, i.e., is formed at least partially or also completely from the electrically insulation material.

It will be understood that when an element is described as being “connected” or “coupled” to another element, the same can be directly connected or coupled to the other element or intermediate elements can be present. In contrast, if an element is described as “directly” “connected” or “coupled” to another element, no intermediate elements are present. Other expressions used to describe the relationship between elements should be interpreted in the same way (e.g., “between” versus “directly between”, “adjacent” versus “directly adjacent”, etc.).

To simplify the description of the various embodiments, at least some of the figures have a Cartesian coordinate system x, y, z, wherein the directions x, y, z are arranged orthogonally to each other. In the embodiments, the x-y plane corresponds to the main surface region of a carrier or substrate (=reference plane=x-y plane), wherein the vertical upward direction with respect to the reference plane (x-y plane) corresponds to the “+z” direction, and wherein the vertical downward direction with respect to the reference plane (x-y plane) corresponds to the “−z” direction. In the following description, the term “lateral” means a direction parallel to the x- and/or y-direction, i.e., parallel to the x-y-plane, whereas the term “vertical” indicates a direction parallel to the +/−z-direction.

In the context of the present description, terms and/or text passages in brackets are to be understood as further explanations, exemplary configurations, additions and/or exemplary alternatives (to the preceding term or the preceding text passage).

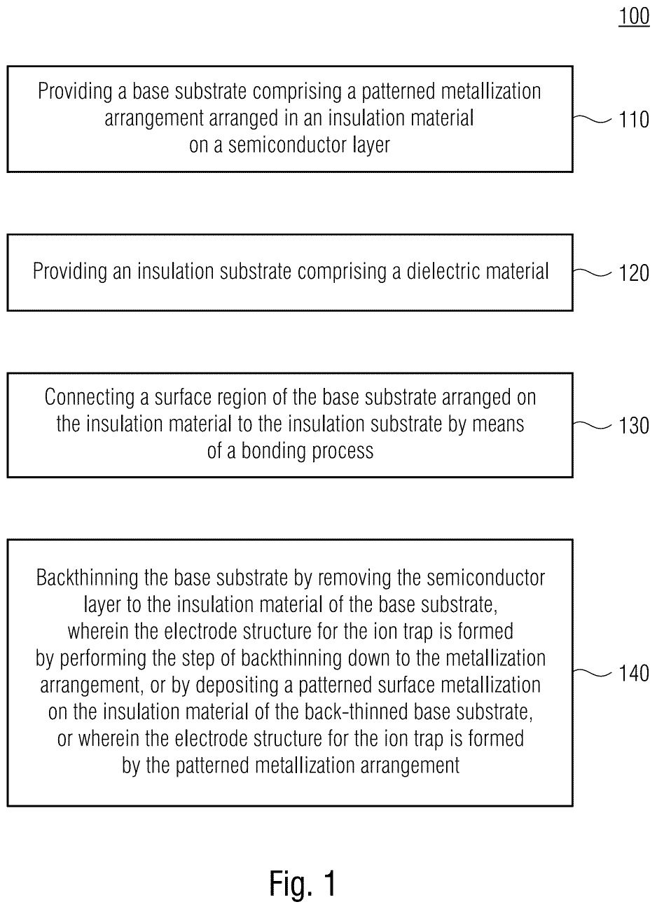

FIG. 1 shows a schematic flow diagram 100 of the inventive manufacturing process according to an embodiment. The method is used to manufacture an electrode structure for an ion trap.

In a step 110, the method includes providing a base substrate comprising a patterned metallization arrangement arranged in an insulation material on a semiconductor layer.

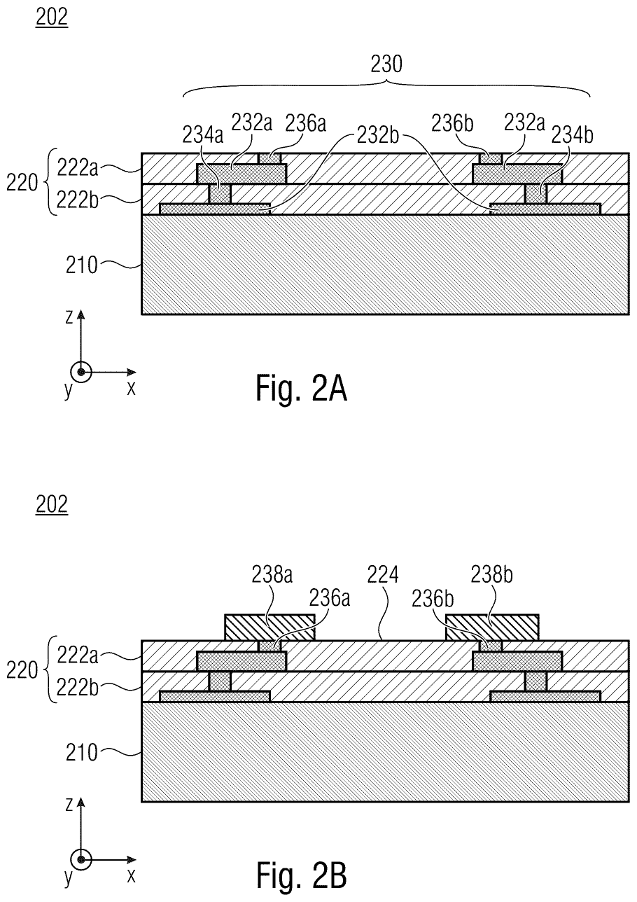

FIG. 2a shows a schematic cross-section of an example of a base substrate 202 with a semiconductor layer 210 and a patterned metallization arrangement 230 arranged in an insulation material 220.

The base substrate 202 can be configured as a standard semiconductor manufacturing substrate or an integrated circuit (IC) substrate. The base substrate 202 (e.g., the semiconductor layer 210 thereof) can include at least one of silicon, germanium, and gallium arsenide. The base substrate can be a wafer, a plurality of wafers, or a part of a wafer (e.g., of a single-crystal semiconductor material). A standard substrate from semiconductor manufacturing or an IC substrate can be manufactured with high precision and scalability or is more easily available.

Furthermore, manufacturing the electrode structure can optionally be combined with a manufacturing process for the standard substrate.

The insulation material 220 of the base substrate 202 can comprise a dielectric from semiconductor manufacturing, such as SiO₂, HfO₂ or GeO₂. The base substrate 202 can optionally include further components (e.g., layers), such as at least one of an oxide layer (e.g., on a surface of the semiconductor layer 210 facing and/or facing away from the insulation material 220) and a material for attaching a surface of the semiconductor layer 210 facing away from the insulation material 220 to a carrier substrate.

Dielectrics from semiconductor manufacturing enable manufacturing the insulation material 220 using standard semiconductor manufacturing process steps. Thus, the metallization arrangement 230 can be formed by patterning the insulation material 220 using standard semiconductor manufacturing process steps so that the metallization arrangement 230 and the electrode structure can be formed in a precise and scalable manner.

In the following description, embodiments are described in which the semiconductor layer 210 includes silicon and the insulation material 220 includes silicon oxide. However, the disclosure is not limited to these examples of materials (or other ones described below).

The metallization arrangement 230 can be configured as a multilayer metallization arrangement. Consequently, the metallization arrangement 230 can have more complex structures so that routing of electric lines within the insulation material 220 is facilitated and electrode structures can be better adapted to electric field needs.

FIG. 2a shows an example of a multilayer metallization arrangement 230 comprising two metallization layers 232a, b. The metallization arrangement 230 comprises first vias 234a, b, each electrically connecting two metallization layers 232a, b to one another. The metallization arrangement 230 can comprise further first vias 234a, b for further metallization layers 232a, b. The metallization arrangement 230 comprises second vias 236a, b, which extend from a (e.g., uppermost) metallization layer 232a to a surface of the insulation material 220. Backthinning to the uppermost metallization layer 232a enables the electrode structure to be formed completely (or almost completely) within the insulation material 220. Therefore, this electrode structure 230 is accessible to forming by means of standard semiconductor manufacturing process steps.

The insulation material 220 can include several insulation material layers 220a, b. At least one insulation layer 220a, b can include one of the metallization layers 232a, b and one of the first or second vias 234a, b, 236a, b. The insulating layers 220a, b can be used as carrier layers for forming the metallization arrangement 230. The step of providing 110 the base substrate can include forming the patterned metallization arrangement 230 arranged in the insulation material 220. Forming an insulation material layer 220a, b can include forming a metallization layer 232a using photolithography and forming first vias 234a, b using photolithography. The metallization arrangement 230 can comprise at least one of gold, copper, nickel, and silver.

FIG. 2b shows a schematic cross-section of an example of a base substrate 202 with metal pads 238a, b.

A surface region 224 of the base substrate 202 (facing away from the semiconductor layer 210) arranged on the insulation material 220 can comprise metal pads 238a, b (e.g., bond pads). At least one (or each) of the metal pads 238a, b is electrically connected to the metallization arrangement 230 (e.g., with the second vias 236a). However, metal pads without electrical connection to metallization arrangement 230 (e.g., for field shielding) can also be provided. The step of providing 110 the base substrate can include forming the metal pads 238a, b on the surface region 224 of the base substrate 202 (e.g., by photolithography).

The metal pads 238a, b can enable the insulation material 220 to be connected to the insulation substrate 250 (e.g., with metal pads of the insulation substrate 250). Further, the metal pads 238a, b can be used for electrically contacting the metallization arrangement 230.

In a step 120, the method includes providing an insulation substrate comprising a dielectric material.

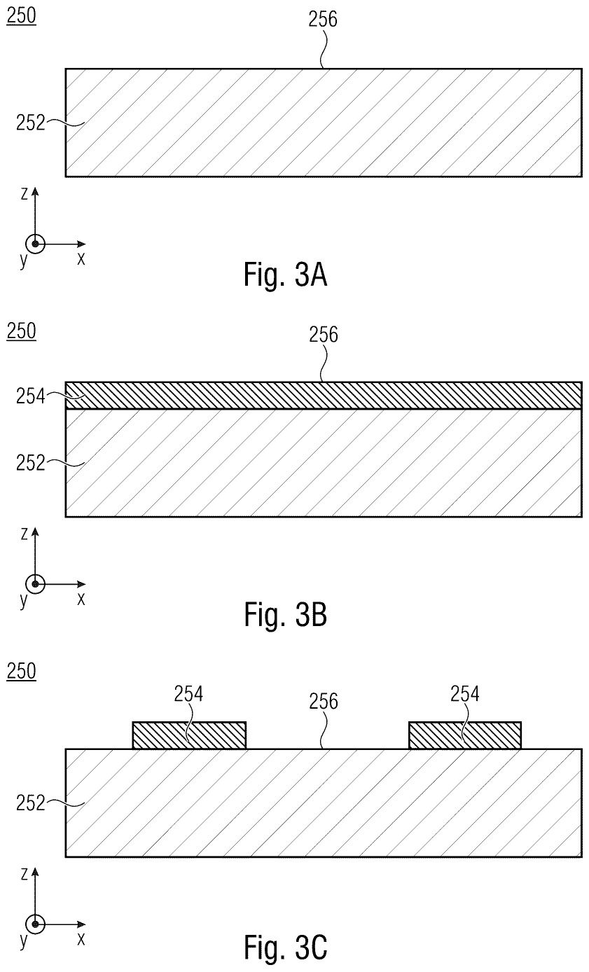

FIG. 3a shows a schematic cross-section of an example of an insulation substrate 250 having a dielectric material 252.

The dielectric material of the insulation substrate 250 can comprise or can be formed from glass, diamond, sapphire, corundum or ceramic. These dielectric materials form a good trade-off between reduction of parasitic capacitances, mechanical stability and compatibility with the base substrate 202.

The insulation substrate 250 can comprise at least substantially the same lateral dimensions (e.g., in the x- and/or z-direction in FIG. 3a) as the base substrate 202. The insulation substrate 250 and the base substrate 202 can have a plate shape (e.g., in the form of a wafer). The insulation substrate 250 can comprise associated metal pads (bond pads).

FIG. 3b shows a schematic cross-section of an example of an insulation substrate 250 with a metal pad 254.

The metal pad 254 completely covers a surface of the insulation substrate 250. Such a metal pad 254 can facilitate electrical contacting due to its size.

The method can include arranging the metal pad 254 on the surface of the insulation substrate 250.

FIG. 3c shows a schematic cross-section of an example of an insulation substrate 250 with several metal pads 254. Several metal pads 254 enable individual electrical contacting and control.

The insulation substrate 250 has a surface region 256, which can be formed of at least one of a surface of the dielectric material 252 and at least one metal pad 254.

The insulation substrate 250 can comprise electric lines (not shown in FIGS. 3a-c), e.g., for conducting control signals from a control device to the metallization arrangement 230. The electric lines of the insulation substrate 250 can be electrically connected to one or more metal pads 254. The electric lines of the insulation substrate 250 can extend at least partially along one or more surfaces of the insulation substrate 250 and/or within the insulation substrate 250. Alternatively or additionally, the insulation substrate 220 can have electric lines that are electrically connected to the metallization arrangement 230. The electric lines can run laterally (in the x- and/or y-direction in FIG. 2b).

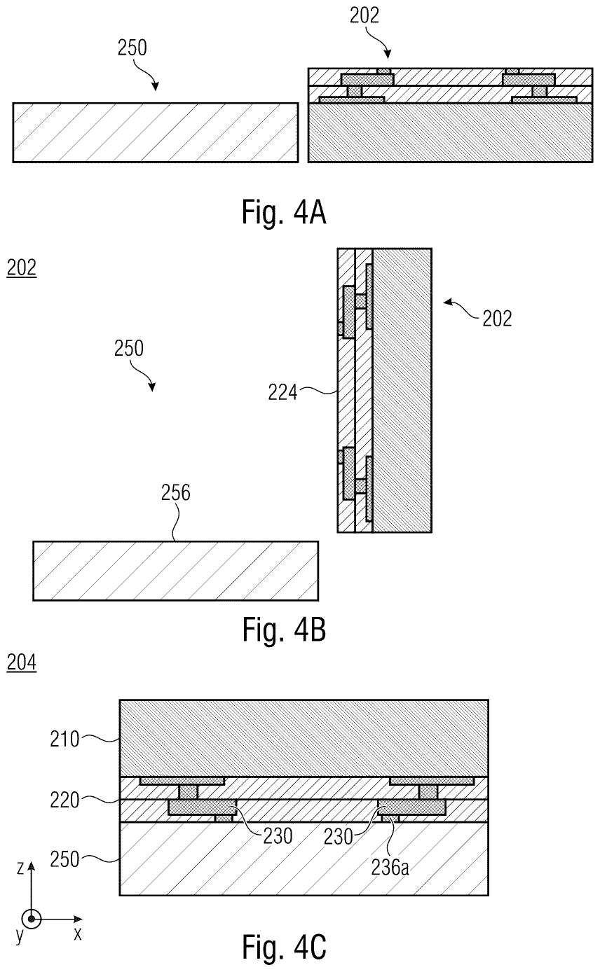

FIGS. 4a-c show a schematic cross-section of arrangements of the base substrate 202 and the insulation substrate 250. The arrangement is shown by way of example using the base substrate 202 of FIG. 2a and the insulation substrate 250 of FIG. 3a. However, any base substrate 202 and insulation substrate 250 described herein can be used.

FIG. 4a shows a schematic cross-section of a separate arrangement of the base substrate 202 and the insulation substrate 250. The base substrate 202 can be oriented with the insulation substrate 250 (for example in a manufacturing apparatus) toward the top (e.g., due to a coating process for forming the insulation substrate 220 and/or protecting the insulation substrate 220).

FIG. 4b shows a schematic cross-section of an arrangement of the base substrate 202 on the insulation substrate 250. Here, the base substrate 202 can be rotated and the surface region 224 of the base substrate 202 can be brought into contact with the surface region 256 of the insulation substrate 250. However, the base substrate 202 and the insulation substrate 250 can also be arranged together in other ways (e.g., rotating together after the base substrate 202 and the insulation substrate 250 have been connected).

In a step 130, the method includes connecting the surface region 224 of the base substrate 202 arranged on the insulation material 220 to the insulation substrate 250 by means of a bonding process.

FIG. 4c shows a schematic cross-section of a bond 204 of the base substrate 202 having the insulation substrate 250.

Performing the bonding process between the insulation material 220 of the base substrate 202 and the insulation substrate 250 can be performed using an oxide/oxide bonding process, or can include at least one oxide/oxide bonding process. The oxide/oxide bonding process can include at least one of heating the bond 204, vibrating the bond 204, and applying an electric current to the bond 204. The oxide/oxide bonding process can include arranging bonding means between the base substrate 202 and the insulation substrate 250.

An oxide/oxide bonding process can be realized using standard semiconductor manufacturing process steps and allows a connection with high mechanical strength. Furthermore, an oxide/oxide bonding process can reduce the use of metals (e.g., in regions where a short-circuit could occur).

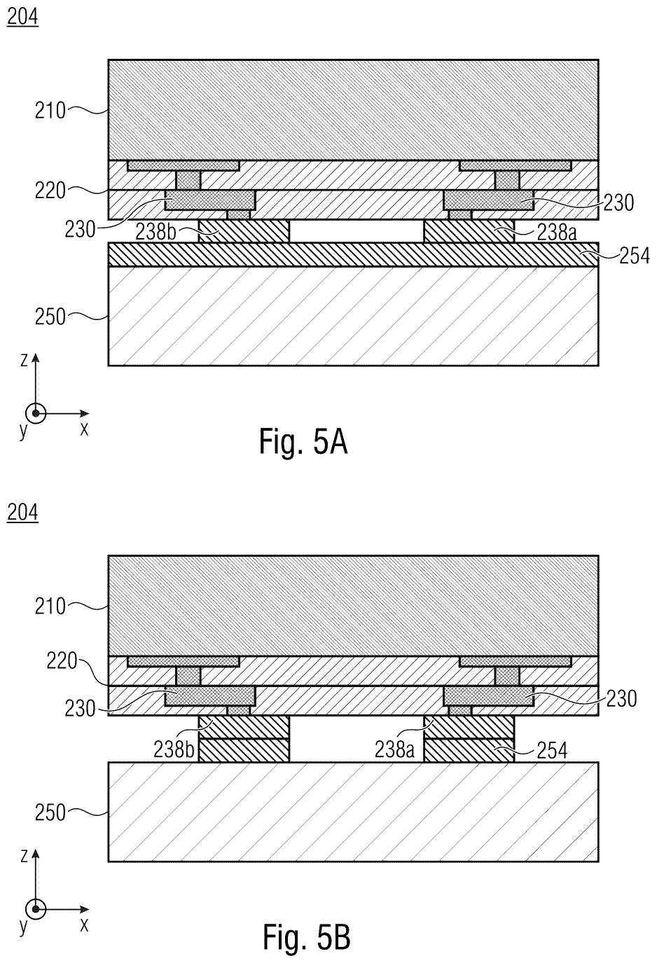

FIG. 5a shows a schematic cross-section of an example of a bond 204 of the base substrate 202 with the insulation substrate 250 after a metal bonding process. The base substrate 202 comprises metal pads 238a, b as described herein with reference to FIG. 2b, for example. The insulation substrate 250 comprises a metal pad as described herein, for example, with reference to FIG. 3b.

Performing the bonding process between the base substrate 202 and the insulation substrate 250 can be performed at the associated metal pads 238a, b, 254 by means of a metal bonding process. The metal bonding process can include at least one of heating, vibrating, and applying an electric current. Since the metal pad covers all (or at least a large part) of a surface of the insulation substrate 250, alignment of the metal pads 238a, b, 254 with each other is simplified.

The metal bonding process can be carried out using standard semiconductor manufacturing process steps and can therefore in a precise and scalable manner. Further, an electrical contact for controlling the electrode structure can be realized.

FIG. 5b shows a schematic cross-section of an example of a bond 204 of the base substrate 202 with the insulation substrate 250 after a metal bonding process. The base substrate 202 comprises metal pads 238a, b as described herein with reference to FIG. 2b, for example. The insulation substrate 250 comprises metal pads as described herein, for example, with reference to FIG. 3c.

Performing the bonding process between the base substrate 202 and the insulation substrate 250 can be performed at the associated metal pads 238a, b, 254 by means of a metal bonding process. The metal bonding process can include at least one of heating, vibrating, and applying an electric current. The plurality of metal bonding pads 238a, b, 254 enables applying different electrical signals to different components of the metallization arrangement 230 (for example, to generate electric fields in an ion trap).

The bonding process can be performed as a combination (hybrid bonding process) of an oxide/oxide bonding process and a metal bonding process. For example, an oxide/oxide bonding process can be performed between the insulation material 220 and the insulation substrate 250. A metal bonding process can, for example, be performed between the metallization arrangement 230 (e.g., a second via 236a and a metallization layer extending to the surface region 224 of the base substrate 202 or metal pads 238a, b) and one or more metal pads 254 of the insulation substrate 250.

A combination (hybrid bonding process) of an oxide/oxide bonding process and a metal bonding process allows a more flexible selection of connection types between different structures of the insulation material 220 and the insulation substrate 250. Thereby, for example, specific electric contacts can be realized by means of the metal bonding process and unwanted metal contacts can be reduced by means of the oxide/oxide bonding process.

The method includes, in a step 140, backthinning the base substrate 202 by removing the semiconductor layer 210 to the insulation material 220 of the base substrate 202. The electrode structure for the ion trap is formed by performing the step 140 of backthinning to the metallization arrangement 230, or by depositing a patterned surface metallization on the insulation material 220 of the back-thinned base substrate 202, wherein the electrode structure for the ion trap is formed by the patterned metallization arrangement.

During the steps of bonding with the insulation substrate 250 and/or backthinning the base substrate 202, the base substrate 202 can be fixed to a carrier substrate, for example made of a dielectric material such as glass, diamond, sapphire, corundum or ceramic. The carrier substrate facilitates handling and enables simultaneous processing of a plurality of base substrates 202.

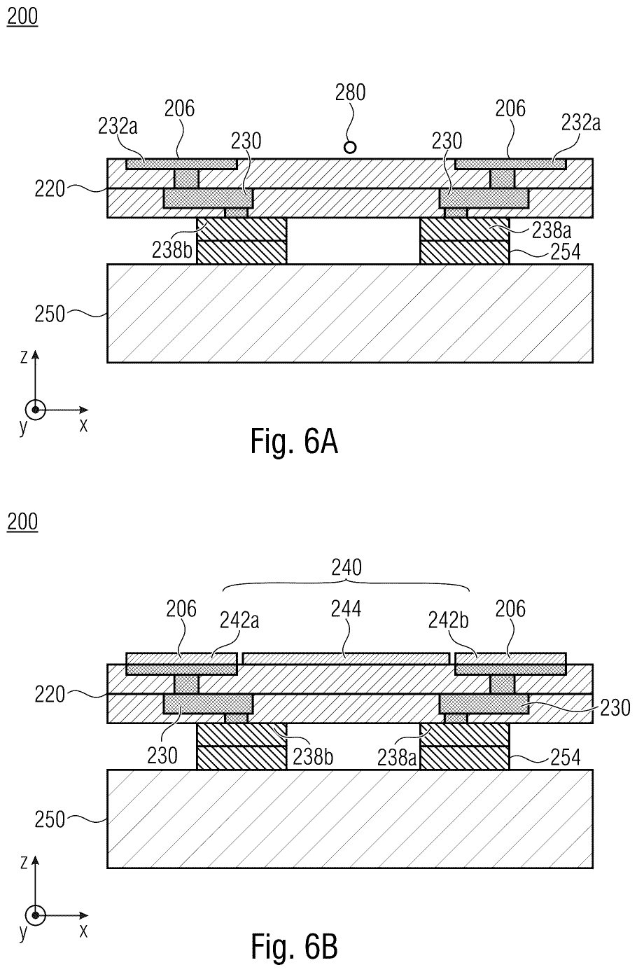

FIG. 6a, b show a schematic cross-section of examples of an electrode device 200 with an electrode structure 206 for an ion trap. The example of the electrode device 200 of FIG. 6a can be realized, for example, by means of a backthinning the bond 204 of FIG. 5b. However, the disclosure described herein is not limited thereto.

FIG. 6a shows a schematic cross-section of an example in which the electrode structure 206 for the ion trap is formed by performing the step of backthinning to the metallization arrangement 230. This exposes uppermost metal surfaces 232a of the metallization arrangement 230 from the insulation material 220, which form the electrode structure 206 (e.g., in the form of surface electrodes). The electrode structure 206 can comprise one, two, three, four or more surface electrodes. The example of the electrode structure 206 shown in FIG. 6a comprises two surface electrodes formed from the metallization layer 232a. By applying an electric signal to the metallization arrangement 230 (e.g., via at least one of metal pads 238a, b, 254 and electric lines of the insulation substrate 250), an electric field can be generated by the electrode structure 206. The electric field can be used to control a position of an ion 280.

The exposed metallization layer (e.g., metallization layer 232a in FIG. 6a) of the metallization arrangement 230 can form the electrode structure for a surface ion trap. For this, the exposed metallization layers 232a can lie in a common plane. The exposed metallization layers 232a, b can be controlled by an electric signal to generate an electric field that holds an ion in a position close to the exposed metallization layer 232a, for example in a gap between two surface electrodes and spaced apart from the insulation material 220. For example, the exposed metallization layers 232a can have a spacing between 50 to 400 μm, e.g., between 100 μm and 200 μm.

Backthinning allows the formation of an at least essentially flat surface, so that the exposed metallization layer or the deposited, patterned surface metallization can also be arranged in a flat plane. This means that the electrode structure formed from this can be used to generate electric fields with good precision, which is advantageous for a surface trap.

FIG. 6b shows a schematic cross-sectional view of an example in which the electrode structure 206 for the ion trap is formed by depositing a patterned surface metallization 240 to the insulation material 220 of the back-thinned base substrate 202. The surface metallization 240 includes a first metallization part 242a, b that is electrically connected to the metallization arrangement 230 (e.g., with at least one metallization layer 232a or a second via 236a). In this case, the electrode structure 206 can be formed by the first metallization part 242a, b. The surface metallization 240 includes a second metallization part 244 that is electrically insulated from the metallization arrangement 230. By applying an electric signal to the metallization arrangement 230 (e.g., via at least one of metal pads 238a, b, 254 and electric lines of the insulation substrate 250), an electric field can be generated by the electrode structure 206 (e.g., the first metallization part 242a, b). The second metallization part 244 can improve electrical shielding.

The surface metallization 240 in FIG. 6b comprises first and second metallization parts 242a, b, 244. Alternatively, the surface metallization 240 can comprise only first metallization parts 242a, b. A second metallization 244 can also be performed for other electrode devices 200 described herein.

The metal pads 238a, b, 254 in FIGS. 5a-6b are configured to be raised (protruding beyond surfaces of the insulation material 220 and the insulation substrate 250). Alternatively, at least one (or all) of the metal pads 238a, b, 254 can be configured to be flush with (or recessed into) the surfaces of the insulation material 220 and the insulation substrate 250.

The deposited patterned surface metallization 240 (e.g., the first metallization parts 242a, b) on the insulation material 220 of the back-thinned base substrate 202 can form the electrode structure 206 for a surface ion trap. The surface metallization 240 (e.g., the first metallization parts 242a, b) can be controlled by an electric signal to generate an electric field that holds an ion in a position close to the patterned surface metallization 240 (e.g., between the first metallization portions 242a, b). For example, two first metallization parts 242a, b can have a distance between 50 to 400 μm, e.g., between 100 μm and 200 μm.

The step of backthinning can be performed to an uppermost (or arranged furthest away from the insulation substrate 250) patterned metallization layer (e.g., at least one of the metallization layers 236a, b) of the multilayer metallization arrangement 230.

In the step of backthinning the base substrate 202, the semiconductor layer 210 of the base substrate 202 can be removed completely (or almost completely, such as 99% or more than 99.9%).

By completely removing the semiconductor layer 210, problems caused by the semiconductor material (e.g., parasitic capacitances and influences on electric fields) can be completely eliminated. Further, a surface of the back-thinned base substrate 202 is formed by a surface of the insulation material 220 (or other intermediate layers such as an oxide layer of the semiconductor material), so that the surface of the base substrate 202 can be controlled (at least primarily) by the surface of the insulation material 220 and not only by backthinning.

Backthinning can include removing a part (e.g., of the dielectric of the insulation material 220 and/or an optional oxide layer between the dielectric and the semiconductor layer 210). The insulation material 220 can be back-thinned less than 1 μm or less than 0.1 μm.

Backthinning can include at least one of dry etching, wet etching and polishing back (e.g., chemical-mechanical polishing).

The method for manufacturing the electrode structure 200 for an ion trap can be performed using standard semiconductor manufacturing process steps. Further, the base substrate can be manufactured using standard semiconductor manufacturing process steps. However, the method allows backthinning of the base substrate 202 so that the amount of material in the semiconductor layer 210 is significantly reduced or completely removed. Common materials used in standard semiconductor manufacturing process steps, such as silicon, can result in parasitic capacitances, which can affect some applications, such as the use in an ion trap. Thus, the method enables the electrode structure 200 to be manufactured using efficient and accurate manufacturing processes and reduces or eliminates disadvantages that materials used in the manufacturing process can cause.

The metallization arrangement 230 embedded in the insulation material 220 can be configured as an antenna structure for providing electric fields to the ion trap. A constant signal (e.g., constant voltage) or an alternating signal (e.g., alternating voltage) can be applied to the metallization arrangement 230. A constant field (DC field) can be generated by means of one part of the electrode structure 206 and an alternating field (RF field) can be generated by means of another part of the electrode structure 206. Based on these signals, the metallization arrangement 230 can generate electric fields as an antenna structure.

Since ion traps can be susceptible to parasitic capacitances, using the metallization arrangement 230 as an antenna structure can improve the operation of an ion trap. In particular, it can extend coherence times of ion states.

The ion trap can be provided for quantum computing applications. Since quantum mechanical calculations are possible within the coherence time, an ion trap with the electrode structure described herein can enable more complex quantum computing applications.

The method can further include a step of forming a recess in the form of a hole or trench in the base substrate 202 through the insulation material 220 of the metallization arrangement 230 down to the semiconductor layer.

As the recess extends through the insulation material of the metallization arrangement 230 (e.g., multilayer metallization arrangement), the recess can form a volume in which electric fields are generated by the electrode structure (and optionally by parts of the multilayer metallization arrangement arranged within the insulation material) that allow positioning of an ion within the recess. Due to the manufacturing described herein, the electrode structures can be precisely formed and allow good control over electric fields within the recess.

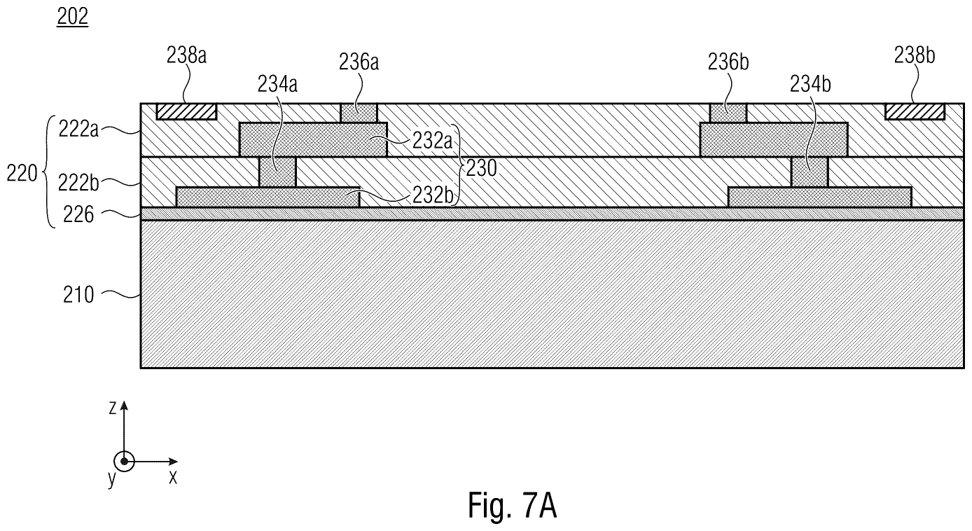

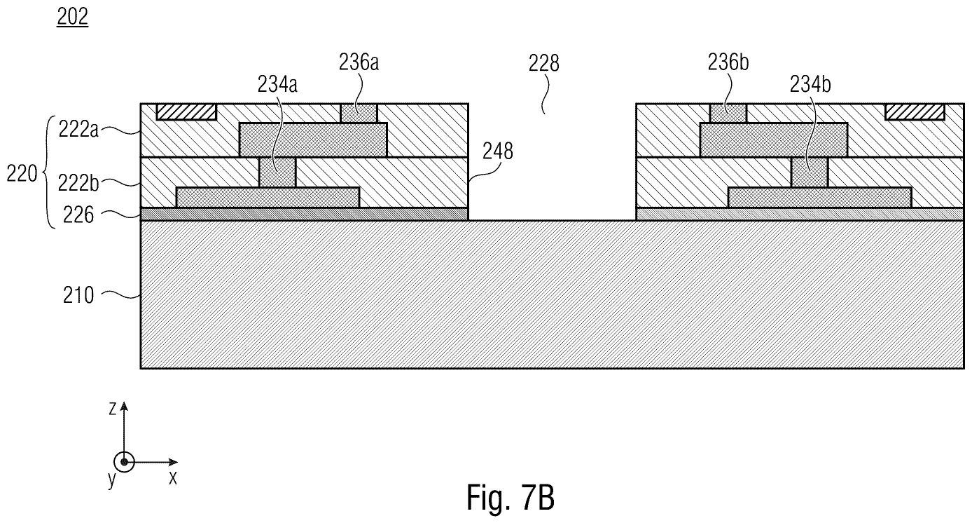

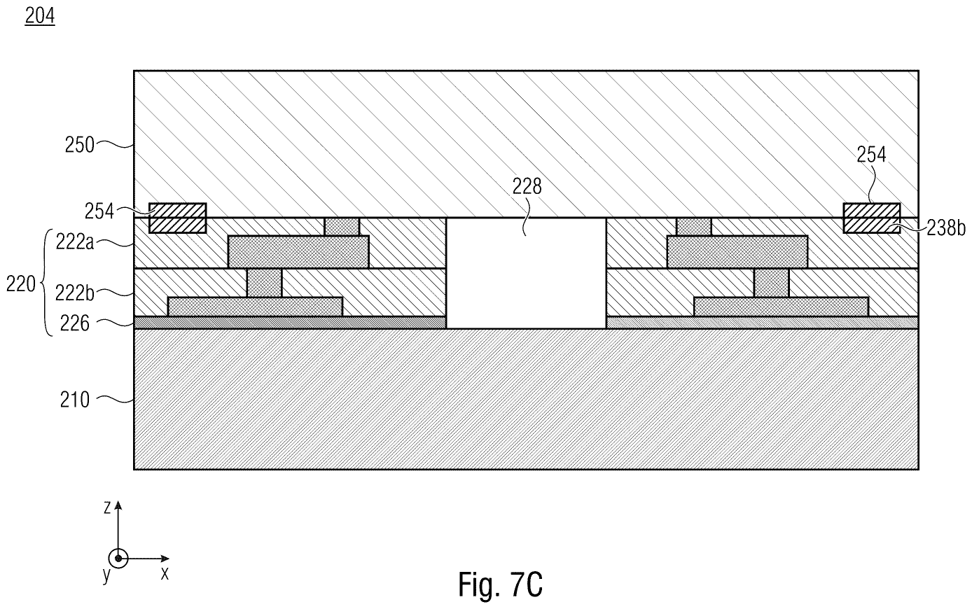

FIG. 7a shows a schematic cross-section of an example of a base substrate 202 before a recess is formed. The recess can be configured in any base substrate 202 (or bond 204) described herein. The base substrate 202 in the example of FIG. 7a can be an implementation of the base substrate 202 of FIG. 2a, wherein the insulation material 220 further comprises an oxide layer 226 (IC insulation oxide, such as an oxide of a material of the semiconductor layer) on a side facing the semiconductor layer 210. The insulation material 220 in FIG. 7b can also have no oxide layer 226. The oxide layer 226 can be part of any insulation material 220 described herein.

FIG. 7b shows a schematic cross-section of the base substrate 202 of FIG. 7a after a recess 228 has been formed.

The recess 228 can also be formed at a different time. For example, the recess 228 can be configured after steps 130 (connecting the base substrate 202 to the insulation substrate 250) and 140 (backthinning the base substrate 202).

The step of forming the recess 228 can be performed by means of hole or trench etching. The recess 228 can also extend into or through the semiconductor layer 210. The recess 228 can have the shape of a cylinder or cube. The recess 228 can have an elongated cuboidal cross-section (e.g., having a longest extension in the y-direction in FIG. 7b). The recess 228 can extend completely through the insulation material 220 in a lateral direction (in the x- and/or y-direction in FIG. 7b).

Hole or trench etching enables precise formation of the recess and can be performed using standard semiconductor manufacturing process steps.

The recess 228 comprises side walls 248. The side walls 248 can be configured to be flat or round. The side walls 248 can be arranged separately from the metallization arrangement 230. In other words, the recess 228 can be shaped such that the recess 228 does not intersect the metallization arrangement 230.

FIG. 7c shows a schematic cross-section of a bond 204 after connecting the base substrate 202 of FIG. 7b to an insulation substrate 250.

In the example in FIG. 7b, the base substrate 202 comprises flush metal pads 238a, b and the insulation substrate 250 comprises flush metal pads 254. Connecting the base substrate 202 to an insulation substrate 250 can be accomplished by means of a metal bonding process between the metal pads 238a, b, 254. Alternatively, connecting can be accomplished by another bonding process described herein. However, the base substrate 202 and/or insulation substrate 250 can include any metal pad 238a, b, 254 described herein. Further, each base substrate 202 and/or insulation substrate 250 described herein can comprise flush metal pads 238a, b, 254.

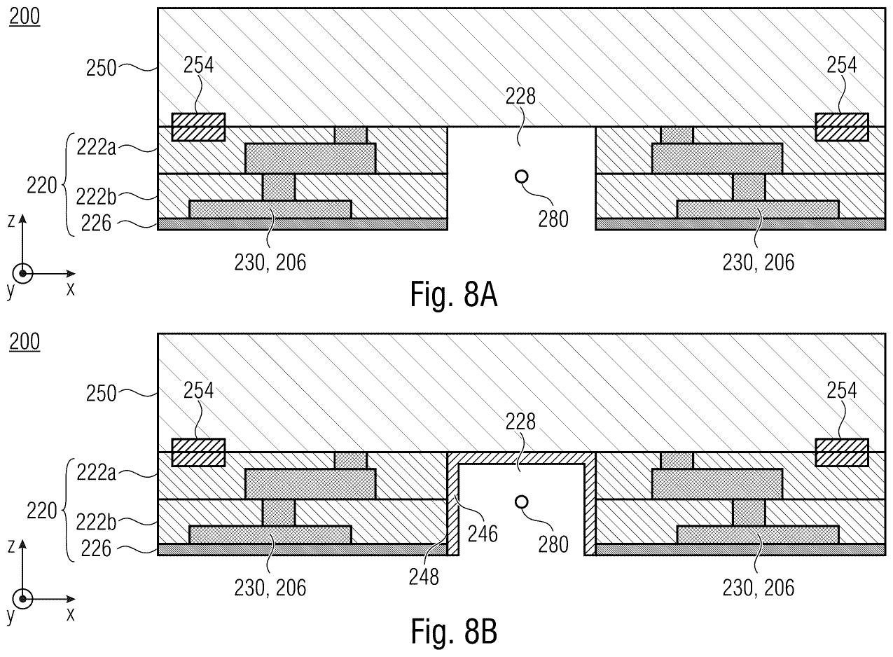

FIG. 8a shows a schematic cross-section of an electrode device 200 with the bond of FIG. 7c after backthinning the base substrate 202 by removing the semiconductor layer 210 to the insulation material 220 of the base substrate 202.

The electrode structure 206 for the ion trap is formed by the patterned metallization arrangement 230. In the example shown in FIG. 8a, backthinning was performed to (or partially into) the oxide layer 226. The metallization arrangement 230 can generate electric fields outside the insulation material 220 without protruding from the insulation material 220. For example, the metallization arrangement 230 can generate electric fields within the recess 228 (surrounded by the metallization arrangement 230 or adjacent to the metallization arrangement 230) for controlling a position of an ion 280 within the recess 228.

Alternatively, the oxide layer 223 can be removed as part of the backthinning process or a separate etching process. Optionally, a surface metallization can be deposited on the insulation material (e.g., for shielding or in electrical contact with the metallization arrangement 230).

FIG. 8b shows a schematic cross-section of the electrode device 200 of FIG. 8a after a metallization has been arranged.

The method can further include a step of arranging a metallization 246 partially or completely on sidewalls 248 of the recess 228 in the insulation material 220 of the back-thinned base substrate 202. The metallization 246 can be arranged on a surface of the dielectric of the insulation material 220. Alternatively or additionally, the metallization 246 can be arranged on a surface of the insulation substrate 250 (which limits the recess 228). If the insulation material 220 comprises an oxide layer 226, the metallization 246 can additionally be arranged on the sidewall 248 of the oxide layer 226. In the example shown in FIG. 8b, the metallization 246 is arranged on surfaces of the insulation material 220, the insulation substrate 250, and the oxide layer 226. The metallization 246 can improve electric shielding of the recess 228. For this, the metallization 246 can be electrically connected to a reference potential (V_{REFERENCE}≠0V) or to ground potential (VGR=0V). The metallization can also be arranged at an earlier stage, such as before connecting to the insulation substrate 250 or backthinning the standard substrate 202.

The metallization 246 can, for example, be configured in a patterned manner (e.g., using optical lithography). The metallization 246 can comprise one or several cut-outs (e.g., holes and/or a recessed edge). The cut-outs can be arranged symmetrically with respect to an axis of symmetry of the recess 228 (e.g., rotationally symmetric with respect to an axis of a cylindrical recess or mirror symmetric with respect to a mirror axis of an elongated or cuboidal recess). The metallization 246 can comprise structures on at least one sidewall 248 and/or one of the surfaces of the insulation substrate 250. A patterned metallization 246 can enable or improve forming of electric fields (e.g., generated by the electrode structure 206).

The metallization 246 can be configured and patterned to allow coupling of an electric (or electromagnetic) field into the recess 228. Thus, the electrode arrangement 208 comprising the electrode structures 206-1, 206-2 can provide electric fields that can be used, for example, to control a position of an ion 280.

Any electrode device 200 described herein (as well as an electrode system 400 described below) can form (or be at least a part of) an ion trap (e.g., a two-dimensional and/or three-dimensional ion trap). Any method for manufacturing an electrode device or electrode system described herein can be a method for manufacturing an ion trap (e.g., a two-dimensional and/or three-dimensional ion trap) or can include a method for manufacturing an ion trap. The method can comprise electrically coupling the electrode structure (or electrode arrangement) to a power supply. The power supply can be configured to provide voltages that lead to the generation of electric fields at the electrode structure (or electrode arrangement). The electric fields can be configured to control a position of an ion (e.g., by providing an AC voltage and/or a DC voltage).

Since the base substrate comprises a semiconductor layer (at least prior to backthinning), the insulation material and/or metallization structure can be manufactured via semiconductor process steps. Such manufacturing methods can have various advantages, such as improved precision, automation and/or patterning process, as well as improved growth conditions (e.g., growing on single-crystal silicon and forming precise oxide layers, for example for the insulation material). Due to connecting to the insulation substrate and backthinning, the semiconductor layer can be completely or at least partially removed, so that the influence of the semiconductor layer can be reduced. An ion trap with the electrode device 200 (or the electrode system 400) has a back-thinned semiconductor layer, so that the influence of semiconductor materials such as silicon can be reduced or avoided. For example, the formation of parasitic capacitances can be reduced. The method makes it possible, for example, to change the substrate material from silicon to glass, quartz or sapphire.

According to an embodiment, a method for manufacturing an ion trap is presented. The method for manufacturing an ion trap can be (partially or completely) by means of semiconductor manufacturing processes. The ion trap can be provided for quantum computing applications. The method can be used to manufacture a 3-dimensional ion trap, or can include manufacturing a 3-dimensional ion trap.

One advantage of the present invention is the potential use of standard semiconductor process elements. Typically, ion traps are manufactured using more complex, expensive and elaborate microprocessing technology and metallization processes. The invention thus enables more cost-effective manufacturing of ion traps and, moreover, above all, a significantly higher quality and reliability of the products.

According to an embodiment, a method for manufacturing an ion trap (e.g., for quantum computing applications) comprises the following steps: Providing a substrate of standard semiconductor manufacturing (e.g., base substrate 202, e.g., IC substrate) that includes an IC multilayer metallization (e.g., metallization arrangement 230) and optional metallization structures (e.g., metal pads 238b) for a substrate bonding process (metal bond pads).

The method can include manufacturing (e.g., recessing) a trench (e.g., recess 228) through one or more dielectrics (e.g., insulation material 220) of the IC substrate (e.g., base substrate 202). Further, the method can include connecting (e.g., bonding) the IC substrate (e.g., base substrate 202) to a second substrate (e.g., insulation substrate 250) comprising a dielectric surface (insulation substrate) to form a substrate stack. Connecting can be performed by means of oxide/oxide bonding and the metal bond pads (e.g., metal pads 238b) on the front side (hybrid bonding process). The method can include backthinning the substrate stack (e.g., including the base substrate 202 and the insulation substrate 250) to the dielectric layer (e.g., insulation material 220) such that the semiconductor layer (e.g., semiconductor layer 210) of the IC substrate (e.g., base substrate 202) is completely (or partially) removed.

Backthinning can take place on a surface of the semiconductor layer facing away from the insulation substrate. Backthinning can take place uniformly (e.g., without patterning and/or masking) across the surface of the semiconductor layer facing away from the insulation substrate. In other words, a thickness of the base substrate can be uniformly reduced by backthinning. The base substrate (e.g., a remainder of the semiconductor layer 210 or the insulation material 252) can form a (e.g., single) planar surface on a back-thinned side (e.g., on a side facing away from the insulation substrate 250).

For example, the IC substrate (e.g., base substrate 202) can include an insulation oxide, one or more inter-metal dielectrics (e.g., insulation material 220), metallization (e.g., metallization arrangement 230), and metal bond pads (e.g., metal pads 238b). The IC substrate can be manufactured using a standard semiconductor manufacturing process. Optionally, a trench etch can be performed through the one or more dielectrics (e.g., down to the IC substrate). The method for can include bonding a front surface to an insulation substrate (e.g., by oxide/oxide bottom or metal hybrid bonding.

According to an embodiment, for example, a 3D integration system is realized having interconnects with the following properties. A structure of surface ion traps can be realized by means of single and/or multilayer metallization on glass, quartz, sapphire or ceramic substrates. To optimize DC/RF fields, grey tone lithographic methods can be used to structure metal surfaces (e.g., of electrode structure 206 and/or electrode arrangement 208) 3-dimensionally. A 3-dimensional Paul ion trap arrangement can be patterned by connecting two or more surface ion traps (e.g., two or more electrode structures 206 or ion traps having electrode structures 206). A mechanical and/or electrical connection of the ion traps to a carrier, which can also be a surface ion trap, can be ensured (e.g., realized) by means of interconnects. According to an embodiment, a method for manufacturing surface ion traps is provided, e.g., by means of single and/or multilayer metallization on glass, quartz, corundum, diamond or ceramic substrates. A 3-dimensional ion trap structure can comprise one or more surface ion traps. The method can include 3-dimensional patterning of an electrode topography using grey tone lithography to modify electric field properties.

A further approach for manufacturing a 3-dimensional trap includes connecting an electrode device to a further electrode device. For the method 300 described below for manufacturing the 3-dimensional trap, the steps of the method 100 described above are equally usable and applicable in part or in whole and in any combination. Structures described in the electrode structure described above can be realized in the 3-dimensional trap partially or completely and in any combination. The technical effects described above also apply to the embodiments described below.

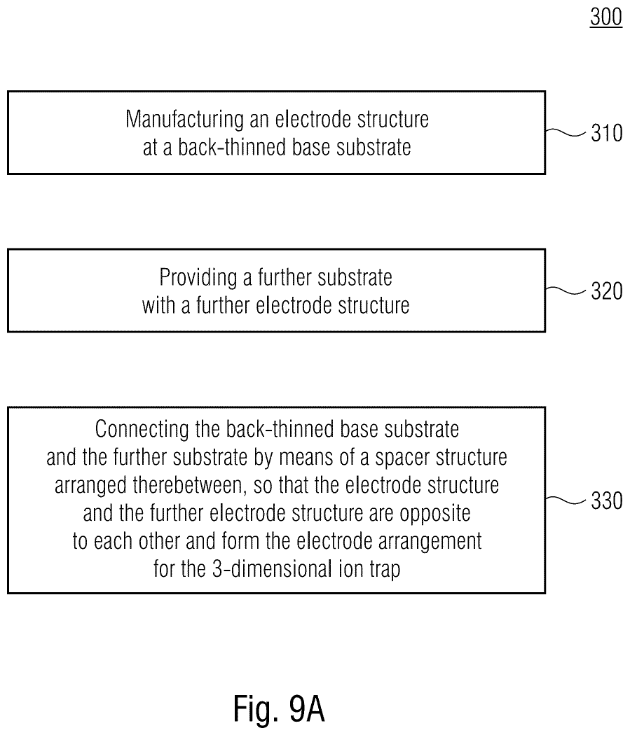

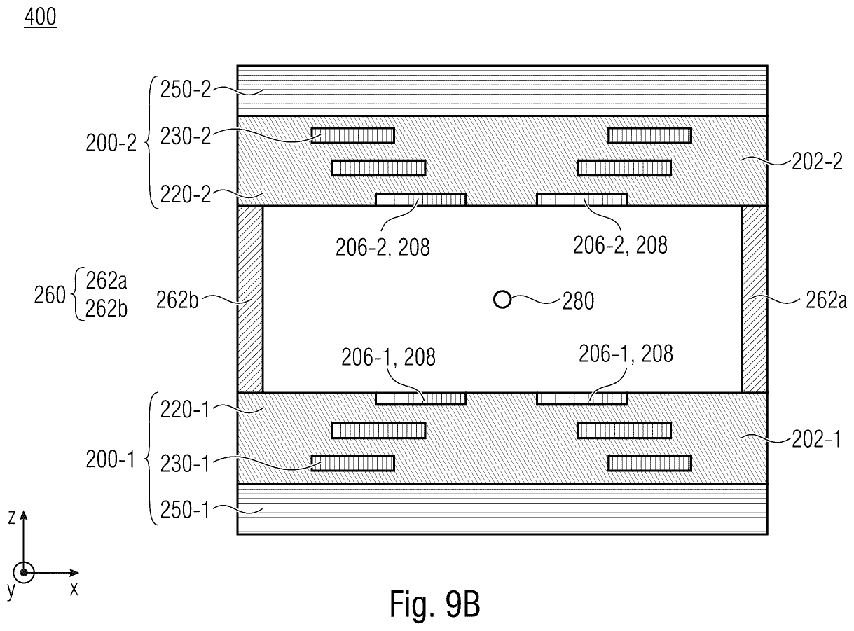

FIG. 9a shows a schematic flow diagram 300 of the inventive manufacturing method according to an embodiment. The method 300 is used to manufacture an electrode arrangement for a 3-dimensional ion trap.

The method includes, in a step 310, performing the method 100 (with steps 110, 120, 130, 140) as described herein to manufacture an electrode structure (for an ion trap) on a back-thinned base substrate.

Therefore, step 310 includes providing a base substrate (see also step 110 of FIG. 1) comprising a patterned metallization arrangement arranged in an insulation material on a semiconductor layer. FIGS. 2a and 2b show examples of a base substrate 202.

Step 310 includes providing an insulation substrate (see also step 120 of FIG. 1) comprising a dielectric material. FIG. 3a to c show examples of an insulation substrate 250.

Step 310 further includes connecting the surface portion 224 of the base substrate 202 arranged on the insulation material to the insulation substrate 250 using a bonding process (see also step 130 of FIG. 1). FIGS. 4 and 4b show examples of an arrangement of the base substrate 202 to the insulation substrate 250. FIGS. 4c, 5a and 5b show examples of a bond 204 including the base substrate 202 and the insulation substrate 250.

Step 310 further includes backthinning the base substrate 202 by removing the semiconductor layer 210 to the insulation material 220 of the base substrate 202.

The electrode structure for the ion trap is formed by performing the step 140 of backthinning to the metallization arrangement 230, or by depositing a patterned surface metallization on the insulation material 220 of the back-thinned base substrate 202, or wherein the electrode structure 206 for the ion trap is formed by the patterned metallization arrangement 230 (see also step 140 of FIG. 1). FIGS. 6a and 6b show examples of an electrode device 200 having a back-thinned base substrate.

In a step 320, the method includes providing a further substrate having a further electrode structure.

The further substrate can have a plate or wafer shape. The substrate can include or consist of a dielectric material, such as glass, diamond, sapphire, corundum or ceramic. The further substrate can include a metal. The further substrate can include, on at least one surface, a surface coating comprising a dielectric material.

The further electrode structure can be arranged on the dielectric material or the surface coating. Providing the further substrate with the further electrode structure can include manufacturing the further substrate with the further electrode structure.

Manufacturing the further electrode structure can include at least one of optical lithography, grey tone lithography, and material deposition. The further substrate can be manufactured using a method with low complexity. For example, the further substrate can be manufactured by shaping metallic electrodes on a glass substrate.

No electric line can be provided through the further substrate, for example.

However, the further substrate can also have a more complex structure. Providing according to step 320 can include, for example, performing any method (100) described herein to manufacture a further back-thinned base substrate having an electrode structure forming the further electrode structure.

In this case, step 320 also includes the steps (of the method 100) of providing and connecting the base substrate and the insulation substrate and backthinning the base substrate, as mentioned with reference to step 310. A further substrate, which includes a further back-thinned base substrate, can enable or facilitate electrical contacting, for example on a side of the further back-thinned base substrate (or also a free space for ions) facing away from the back-thinned base substrate and/or the further insulation substrate.

However, providing according to step 320 can include only portions and/or variations of the method 100. For example, step 320 can include providing a base substrate according to step 110 but without steps 120, 130 and 140. The further substrate can be configured without an insulation substrate. In another example, in a variation of step 110, the method can include providing a base substrate having a metallization arrangement on (instead of in) an insulation material on a semiconductor layer.

Manufacturing the electrode structure can comprise any process step as described herein in any combination. The electrode structure can comprise any feature as described herein in any combination. Manufacturing the further electrode structure can comprise any method step as described herein in any combination. The further electrode structure can comprise any feature as described herein in any combination.

The electrode structure and the further electrode structure can have (at least essentially) identical features or be manufactured by identical method steps. The electrode structure and the further electrode structure can, for example, be manufactured by the same manufacturing apparatus or be manufactured in parallel in the same manufacturing process.

Alternatively, the electrode structure and the further electrode structure can be manufactured by different manufacturing steps and/or comprise different features.

In a step 330, the method includes connecting the back-thinned base substrate and the further substrate (e.g., a further back-thinned base substrate) by means of a spacer structure arranged therebetween so that the electrode structure and the further electrode structure face each other (vertically) and form the electrode arrangement for the 3-dimensional ion trap.

An insulation material of the electrode device and an optional further insulation material of a further electrode device (e.g., the further substrate or a further back-thinned base substrate) can face each other. An insulation substrate of the electrode device and an optional further insulation substrate of the further electrode device can face away from each other. At least part of the electrode structure and the further electrode structure (e.g., some or all of the electrodes and/or conductive paths of the two electrode structures) can be arranged in mirror symmetry, with a mirror plane passing through the spacer structure (e.g., perpendicularly). If the further substrate includes a further back-thinned base substrate, at least a part of the two back-thinned base substrates (e.g., at least a part of the electrode structures, the metallization arrangements, the insulation materials, or any combination thereof) can be arranged in mirror symmetry, with a mirror plane passing through the spacer structure (e.g., perpendicularly).

FIG. 9b shows a schematic cross-section of an example of an electrode system 400 having an electrode arrangement 208 for a 3-dimensional ion trap. The electrode system 400 includes a spacer structure 260 between an electrode device 200-1 and a further electrode device 200-2. In the example of the electrode system 400 shown in FIG. 9b, the further substrate is formed by the further electrode device 200-2. Alternatively, the electrode system 400 can include any other further substrate described herein.

The electrode device 200-1 includes an insulation substrate 250-1 and a back-thinned base substrate 202-1 including an insulation material 220-1 in which a metallization arrangement 230-1 is arranged.

The further electrode device 200-2 includes a further insulation substrate 250-2 and a further back-thinned base substrate 202-2 including a further insulation material 220-2 in which a further metallization arrangement 230-2 is arranged.

The spacer structure 260 in the example of FIG. 9b comprises two spacer elements 262a, b. Alternatively, the spacer structure 260 can comprise only one or more (e.g., three, four, five, or more) spacer elements 262. The spacer structure 260 (or a spacer element thereof) can have one or more (continuous) openings. The opening can be configured (e.g., together with the electrode structure 206-1 and the further electrode structure 206-2) to (at least partially) limit a volume for a 3D ion trap. For example, the spacer structure 260 can include a plate structure having one or more openings therethrough, each arranged between electrode structures 206-1, 206-2 and further electrode devices 200-1, 200-2.

The spacer structure 260 can comprise a dielectric material, such as glass, diamond, sapphire, corundum, or ceramic.

In the step of connecting the back-thinned base substrate 202-1 and the further back-thinned base substrate 202-2, the spacer structure 260 can be configured as a spacer substrate (e.g., having a plate-like structure) and can be arranged between the back-thinned base substrate 202-1 and the further back-thinned base substrate 202-2.

The spacer substrate can comprise a dielectric material, such as glass, diamond, sapphire, corundum or ceramic. The spacer substrate can comprise a metal coating on at least one lateral side (which is directed, for example, towards a volume in which an ion is to be held). The metal coating can be electrically connected to a ground potential or a reference potential. For example, the metal coating can be electrically connected to a part of at least one of the electrode arrangement 208, the electrode structure 206-1, and the further electrode structure 206-2 (e.g., one, two, or more electrodes), which in turn can be electrically connected to a ground potential or a reference potential. Another (or remaining) part of the electrode structure 208 can, for example, form a controllable electrode arrangement for a 3D ion trap. Alternatively, the entire electrode arrangement 208 can form a controllable electrode arrangement for a 3D ion trap.

The spacer structure (or a part thereof) can be formed on the insulation material 220-1 or 220-2) by material deposition.

The base substrate 202-1 can be fixed to a carrier substrate, e.g., made of a dielectric material such as glass, diamond, sapphire, corundum or ceramic, during the steps of connecting to the insulation substrate 250-1, backthinning the base substrate 202-1 and connecting to the further substrate (e.g., having the further back-thinned base substrate 202-2). The carrier substrate facilitates handling and enables simultaneous processing of a plurality of (base) substrates 202-1, 202-2.

The electrode arrangement 208 includes electrode structures 206-1, 206-2 and allows the generation of electric fields that can be used, for example, to control a position of an ion 280. The electrode arrangement 208 can be controlled with a common signal. Alternatively, the electrode structures 206-1, 206-2 can be controlled with different signals. Individual electrodes of the same electrode structure 206-1, 206-2 can be controlled with different signals. Optionally, electrodes of different electrode structures 206-1, 206-2 can be controlled with the same signal (e.g., to generate a quadrupole field distribution).

In the example of the electrode system 400 illustrated in FIG. 9b, the electrode devices 200-1, 200-2, the back-thinned base substrates 202-1, 202-1, the metallization arrangements 230-1, 230-2, and the electrode structures 206-1, 206-2 are arranged with mirror symmetry with respect to a mirror plane through the spacer structure 260 (parallel to the x and y axes). Alternatively, the mirror symmetry can extend to any combination of the above components.

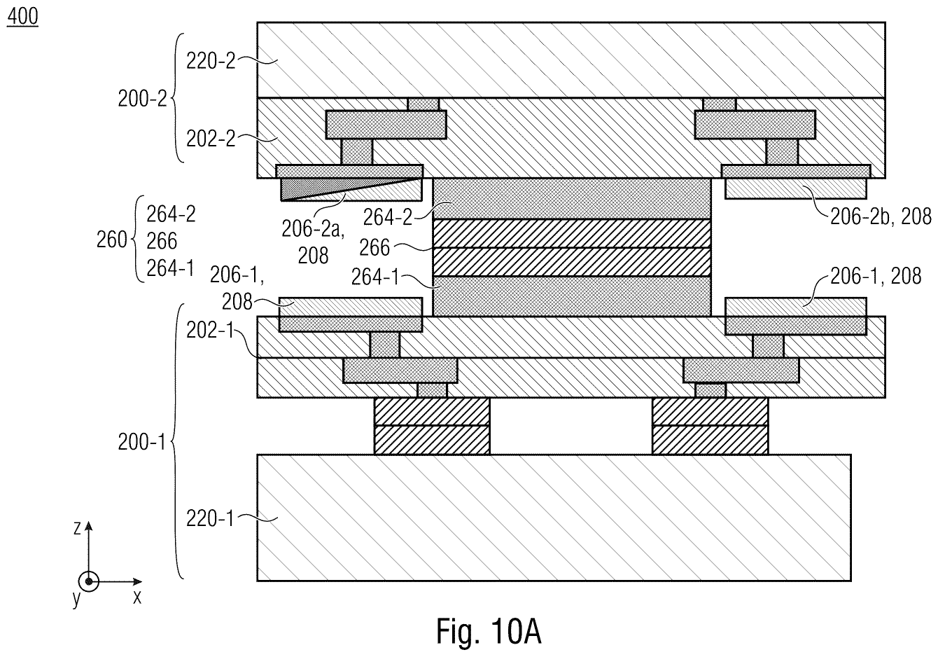

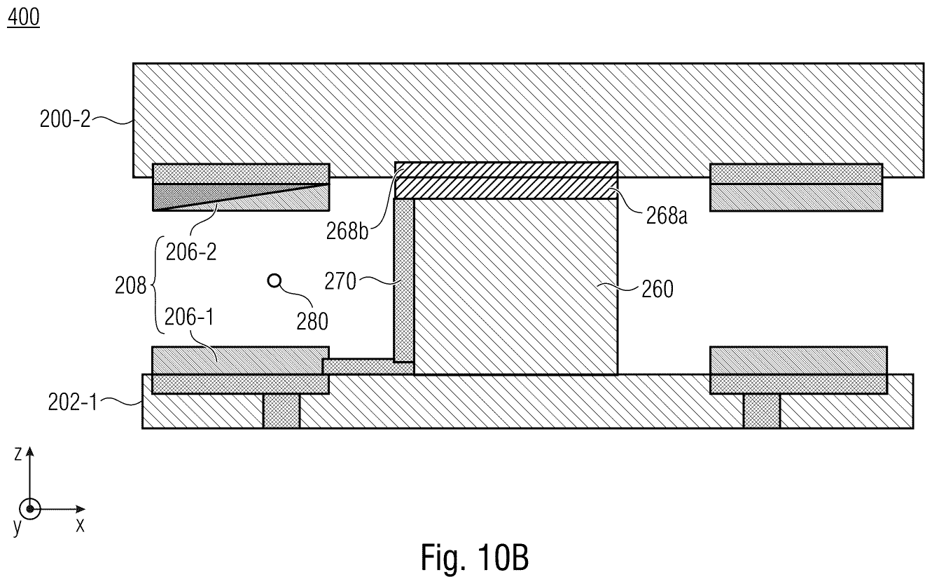

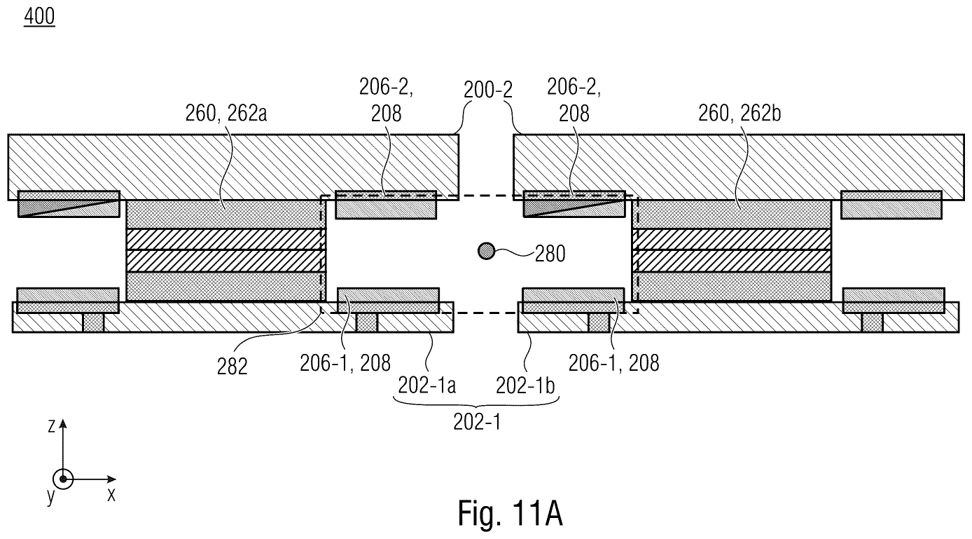

FIG. 10a shows a schematic cross-section of another example of an electrode system 400 with an electrode arrangement 208 for a 3-dimensional ion trap.

The method for manufacturing the electrode arrangement 208 can further include arranging an interconnect structure 264-1 on the back-thinned base substrate 202-1 (e.g., on the insulation material 220-1) and another interconnect structure 264-2 on the further substrate (e.g., another back-thinned base substrate 202-2 (e.g., on the insulation material 220-1)). Arranging the interconnect structures 264-1, 264-2 can take place by material deposition or an oxide/oxide bonding process on the respective insulation material 220-1, 220-2. In the example of the electrode system 400 shown in FIG. 10a, the further substrate is formed by the further electrode device 200-2. Alternatively, the electrode system 400 can include any other further substrate described herein.

The method can further include connecting the back-thinned base substrate 202-1 and the further substrate (e.g., the further back-thinned base substrate 202-2) by connecting the opposing interconnect structures 264-1, 264-2, wherein the connected interconnect structures 264-1, 264-2 form (at least in part) the spacer structure 260.

The opposing interconnect structures 264-1, 264-2 enable a mechanical and/or electrical connection between the (base) substrates 202-1, 202-2. In the case of an electrical connection, an arrangement of electric lines of the electrode system 400 can be simplified. For example, an electric line can be routed from an electrode structure 206-1 via the spacer structure 260 to the side of the electrode structure 206-2 for easier bundling of electrical conductors.

Such an arrangement allows, for example, electrical signals to be applied to only one side of the electrode system 400 (e.g., for one-sided control). For example, a part of the electrical signals can be applied to a part of the metallization arrangement 230 that is electrically connected to the electrode arrangement 206-1, and a further part of the electrical signals can be applied to a further part of the metallization arrangement 230 that is electrically connected to the further electrode arrangement 206-2. Further, the metallization arrangement 230 can include other portions that are connected to other components (e.g., one or more metallizations that are electrically connected to a ground potential or a reference potential via the metallization arrangement 230, for example). Electrical conduction via the spacer structure 260 can thus allow for more flexible and/or easier electrical connection and control. Further, requirements on the further substrate can be reduced as, for example, an electrical connection through an optional further back-thinned base substrate 202-2 and/or through an optional further insulation substrate 250-2 can be omitted.

For example, the further substrate can comprise a further electrode structure on its surface that is connected to an electric line on the spacer structure 260. However, an electric line on the spacer structure 260 is not necessary for a further substrate with low complexity (e.g., without a further back-thinned base substrate). The further electrode structure can also be controlled via other electric lines. Further electric lines can, for example, be routed along a surface of the further substrate from a free space for the 3D ion trap. Further, the substrate can include metal (e.g., locally limited and/or at least partially separated from the further electrode structure by an electrically insulating layer), which can enable an electric line for control.

Connecting the opposing interconnect structures 264-1, 264-2 can take place by means of a bonding process, such as an oxide/oxide bonding process or a metal bonding process. Prior to connecting the opposing interconnect structures 264-1, 264-2, a metallization can be deposited on at least one of the interconnect structures 264-1, 264-2. In the example shown in FIG. 10a, the interconnect structures 264-1, 264-2 are connected by means of a metal connection 266 (e.g., to provide one or more conductive traces).

In the step of connecting the back-thinned base substrate 202-1 and the further substrate (e.g., the further back-thinned base substrate 202-1), (at least) two laterally adjacent electrode structures 206-1 of the back-thinned base substrate 202-1 can be arranged vertically opposite to two laterally adjacent electrode structures 206-2a, 206-2b of the further substrate (e.g., the further back-thinned base substrate 202-2). As a result, different electric fields can be generated when electric signals are applied to the electrode structures 206-1, 206-2a, 206-2b. The electrode structures 206-1, 206-2 can comprise at least substantially identical dimensions (e.g., show mirror symmetry). The vertically opposed arrangement can improve symmetry of these electric fields.

The two vertically opposite pairs of electrode structures can form the controllable electrode arrangement of the 3D ion trap (e.g., for quantum computing applications). As the pairs of electrode structures are opposite each other, electric fields that can hold an ion in a three-dimensional volume between the electrode structures can be generated more easily.

The method can further include patterning the electrode structure 206-1, 206-2a, 206-2b of the back-thinned base substrate 202-1 and/or the further substrate (e.g., the further back-thinned base substrate 202-2), e.g., using grey tone lithography, to obtain a three-dimensionally patterned electrode structure 206-1, 206-2a, 206-2b of the electrode arrangement 208. The grey tone lithography can include moving a light mask during illumination and/or using a light mask having a varying degree of light transmission.

In the example shown in FIG. 10a, the electrode structure 206-2a has been patterned in order to obtain a three-dimensionally patterned electrode structure 206-2a.

Alternatively, several or all of the electrode structures 206-1, 206-2a, 206-2b can be configured as three-dimensionally patterned electrode structures 206-1, 206-2a, 206-2b. Three-dimensional electrode structures can improve flexibility in a shaping and optimization of electric fields. This can improve the control of an ion in the three-dimensional ion trap.

FIG. 10b shows a schematic cross-section of a further example of an electrode system 400 for a 3-dimensional ion trap.

The electrode system 400 includes an electrode arrangement 208 with electrode structures 206-1, 206-2 that can generate electric fields to control a position of an ion in the 3-dimensional ion trap.

A back-thinned base substrate 202-1 (shown only schematically in FIG. 10b) is connected to a spacer structure 260 comprising a metallization 268a. The metallization 268a is electrically connected to an electrode structure 206-1 of the base substrate 202-1 by means of a metal connection 270 (e.g., a conductive trace, such as a metallic conductive trace). A further substrate 200-2 comprises a further metallization 268b.

Connecting the back-thinned base substrate 202-1 and a further substrate 200-2 (only schematically shown in FIG. 10b) can take place by means of a metal bonding process between the metallization 268a and the further metallization 268b. Consequently, the electrode structure 206-1 comprises an electrical connection to the further substrate 200-2 via the metal bond 270 and the metallizations 268a, b. Therefore, electric connections for the electrode system 400 can be bundled on the side of the further base substrate 202-2 (e.g., for controlling the electrodes 206-1, 206-2 with the same signal). Optionally, the metal connection 270 can be configured in the form of an electrode extension of the electrode structure 206-1. The electrical conductor described above with reference to FIG. 10a is an example of the metal connection 270. Therefore, the metal connection 270 can be configured and used like the electrical conductor described above. Consequently, the advantages disclosed above for the electrical conductor also apply to the metal connection 270. Due to the metal connection 270, one or several (or all) electrodes of the further electrode structures 270 can be controlled via the electrode structure of the back-thinned base substrate 202-1 (e.g., for one-sided control). The electrode system 400 can be configured to be controlled from only one side via one or several metal connections 270. For example, the further substrate 200-2 can be provided without electric lines through the further substrate 200-2 (as illustrated schematically in FIG. 10b).

The metal connection 270 (and/or the configuration described with reference to FIG. 10a in the form of the electric line via the spacer structure 260) can also be combined with a further back-thinned base substrate 202-2. This can provide more flexibility for controlling the electrode arrangement 208. For example, electrodes can be used to generate electric fields for the 3D ion trap via metallization arrangements of both back-thinned base substrates 202-1, 202-2. The electrode system 400 can be configured to be controlled from two sides (e.g., for a two-sided or double-sided control) (e.g., by means of the back-thinned substrate 202-1 from a first side and by means of the further back-thinned substrate 202-2 from a second side). Further, an electrode (or multiple electrodes) of the back-thinned base substrate 202-1 (and/or the further back-thinned base substrate 202-2) can be connected to metallization surfaces of both back-thinned base substrates 202-1, 202-2 via the metal connection 270 (and/or via the electrical lead over the spacer structure 260). The metallization surfaces can then, for example, be electrically connected together to a ground potential or a reference potential.

FIG. 10b shows, by way of example, only one metal connection (e.g., one or more conductive traces) 270. The metal connection 270 can be electrically connected (for example, to apply a common electrical signal) to one, several, or all of the electrodes of the further electrode structure 206-2. To this end, electric connections (not shown in FIG. 10b) can be provided along a surface of the further substrate between the further metallization 268b and electrodes of the further electrode structure 206-2. Alternatively, the electrode system 400 can comprise more than one metal connection 270 (e.g., at the same spacer structure 260 and/or at different spacer structures 260). Further, the electrode system 400 can comprise more than one metallization 268a and more than one further metallization 268b). A plurality of metal connections 270 can allow individual electric connections to electrodes of the further electrode structure 206-2. In the same manner, the electrode system can include a plurality of electric lines across the spacer structure 260.

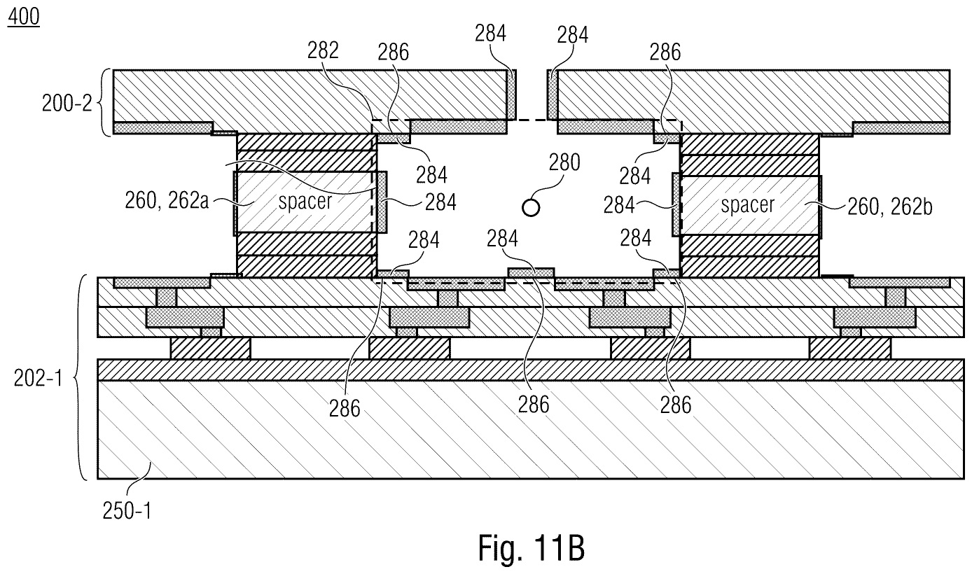

FIG. 11a shows a schematic cross-section of a further example of an electrode system 400 for a 3-dimensional ion trap.

The electrode system 400 includes a back-thinned base substrate 202-1 (illustrated only schematically in FIG. 11a) and a further substrate 200-2 (illustrated only schematically in FIG. 11a). The base substrate 202-1 includes an electrode structure 206-1 and the further substrate 200-2 includes a further electrode structure 206-2, wherein the electrode structures 206-1, 206-2 are part of an electrode arrangement 208. In FIG. 11a, the back-thinned base substrate 202-1 comprises an insulation substrate, but this is not shown in FIG. 11a. The further substrate 200-2 can be any substrate 200-2 described herein (e.g., including a dielectric with a further electrode structure or including a further back-thinned base substrate).

The electrode arrangement 208 can be used to control a position of an ion 280 between the electrode structures 206-1, 206-2. As an example, the further electrode structure 206-2 includes an electrode with a three-dimensionally patterned electrode structure. Alternatively, none, several or all of the electrodes of the electrode structures 206-1, 206-2 can have a three-dimensionally patterned electrode structure.

The back-thinned base substrate 202-1 (and/or the further substrate 200-2) can include a plurality of base substrate portions 202-1a, 202-1. The base substrate portions 202-1a, 202-1 can each comprise an electrode structure 206-1 that is part of the electrode arrangement 208.

As shown by way of example in FIG. 11a, a free space 282 can be formed between adjacent spacer structures 262a, b during the step of connecting the back-thinned base substrate 202-1 and the opposing further substrate 200-2.

The method for can further include arranging a metallization surface partially or completely on non-metallic sidewall regions of the free space 282.

FIG. 11b shows a schematic cross-section of another example of an electrode system 400 for a 3-dimensional ion trap with a metallization surface 284 on non-metallic sidewall regions.

The electrode system 400 includes a back-thinned base substrate 202-1 and a further substrate 200-2, between which spacer structures 262a, b are arranged. The further substrate 200-2 can be implemented as any further substrate described herein (e.g., including a further back-thinned base substrate 202-2).

As shown by way of example in FIG. 11b, a free space 282 can be formed between adjacent spacer structures 262a, b (e.g., spacers) during the step of connecting the back-thinned base substrate 202-1 and the opposing, further substrate 200-2.

The free space 282 comprises (at least prior to arranging a metallization surface) non-metallic sidewall regions 286, such as on surfaces of an insulation material of the (base) substrates 202-1, 200-2 and surfaces of spacer structures 262a, b. FIG. 11b shows metallization surfaces 284 arranged partially or completely on the non-metallic sidewall regions 286 of the free space 282.

The metallization surfaces 284 can improve shielding of the free space 282 and thus control of electric fields in the free space 282. Several or all of the metallization areas 284 can be electrically connected to a ground potential or a reference potential. The several or all of the metallization areas 284 can be electrically connected to the ground potential or the reference potential via one or several electrodes of the electrode devices 208 (and optionally via one or several metal connections not shown in FIG. 11b, such as metal connection 270 in FIG. 10b).

As indicated in FIGS. 10a to 11b, the electrode systems 400 can comprise further electrode structures beyond the spacer structure 260, which can be part of a further electrode device. Consequently, an electrode system 400 can comprise a plurality of electrode devices 208, each separated by a spacer structure 260.

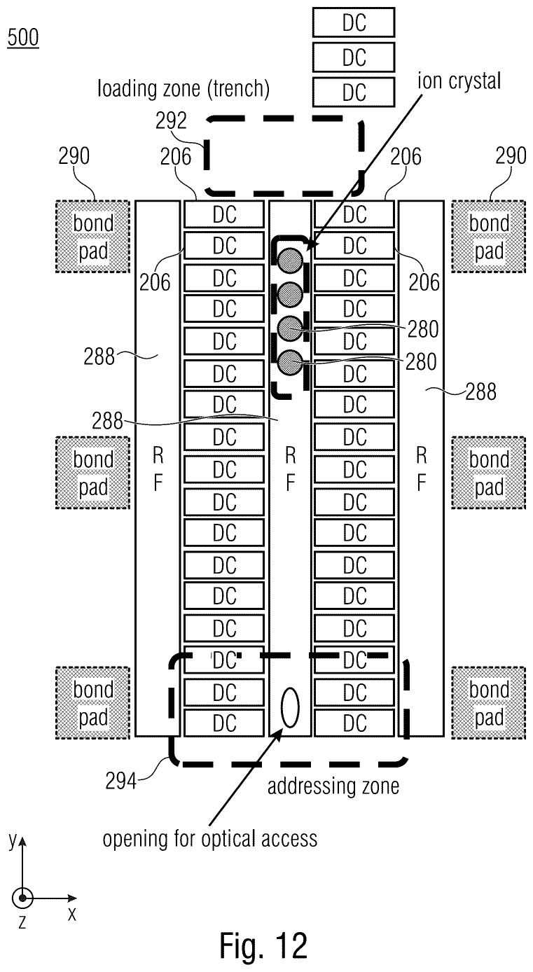

FIG. 12 shows a schematic top view of an example of an ion trap 500 with an electrode device. The ion trap 500 can be manufactured by a method described herein (or by a method that includes a manufacturing method described herein). For example, the ion trap 500 can have a dimensional Paul ion trap arrangement. Such an arrangement can provide a better electric field distribution than surface traps.

Any electrode device 400 and/or electrode structure 206 described herein can be implemented in the ion trap.

The ion trap 500 comprises a plurality of electrode structures 206 (of which, for clarity, only the top four electrode structures 206 are provided with reference numbers in FIG. 12) arranged in a row. The electrode structures 206 shown in FIG. 12 can be, for example, electrode structures 206 of a further substrate 200-2 (e.g., including a further back-thinned base substrate 202-2). The electrode structures 206 are operated with direct voltage (DC). Further, the ion trap comprises three common longitudinal electrodes 288 along the row of electrode structures 206, which are operated with alternating voltage (RF). The ion trap 400 comprises bond pads 290, which are electrically connected, for example, to the electrode structures 206 and the longitudinal electrodes 288.

The electrode structures 206 and the longitudinal electrodes 288 generate electric fields due to the respective applied DC and AC voltages, which allow controlling the positions of ions in the ion trap. For example, in FIG. 12, four ions 280 are arranged in a row to jointly form an ion crystal.

The electrode structures 206 and the longitudinal electrodes 288 also allow control of a movement of the ions 280 along the longitudinal electrodes 288. Thus, electric fields can be generated by means of the electrode structures 206 and the longitudinal electrodes 288 to move ions from a charging zone 292 to a free space between the electrode structures 206 and/or to an addressing zone 294. The addressing zone 294 comprises optical access to, for example, optically manipulate ions 280 (e.g., excite and induce coupling between ions 280).

The plurality of electrode structures 206 can be precisely manufactured with the method described herein, wherein back-thinned base substrates have reduced parasitic capacitances. Therefore, the coherence time of ionic states can be extended.

Although some aspects have been described in the context of an apparatus, it is obvious that these aspects also represent a description of the corresponding method, such that a block or device of an apparatus also corresponds to a respective method step or a feature of a method step. Analogously, aspects described in the context of a method step also represent a description of a corresponding block or detail or feature of a corresponding apparatus. Some or all of the method steps may be performed by a hardware apparatus (or using a hardware apparatus), such as a microprocessor, a programmable computer or an electronic circuit. In some embodiments, some or several of the most important method steps may be performed by such an apparatus. Depending on certain implementation requirements, embodiments of the invention can be implemented in hardware or in software or at least partly in hardware or at least partly in software. In the preceding detailed description, various features have been grouped together in examples in part to streamline the disclosure. This type of disclosure should not be interpreted as intending that the claimed examples have more features than are explicitly stated in each claim. Rather, as the following claims reflect, subject matter may be found in fewer than all of the features of a single disclosed example. Consequently, the following claims are hereby incorporated into the detailed description, and each claim may stand as its own separate example. While each claim may stand as its own separate example, it should be noted that although dependent claims in the claims refer back to a specific combination with one or more other claims, other examples also include a combination of dependent claims with the subject matter of any other dependent claim or a combination of any feature with other dependent or independent claims. Such combinations are encompassed unless it is stated that a specific combination is not intended. It is further intended that a combination of features of a claim with any other independent claim is also encompassed, even if that claim is not directly dependent on the independent claim.

While this invention has been described in terms of several advantageous embodiments, there are alterations, permutations, and equivalents, which fall within the scope of this invention. It should also be noted that there are many alternative ways of implementing the methods and compositions of the present invention. It is therefore intended that the following appended claims be interpreted as including all such alterations, permutations, and equivalents as fall within the true spirit and scope of the present invention.

1. A method for manufacturing an electrode structure for an ion trap, comprising:
providing a base substrate comprising a patterned metallization arrangement arranged in an insulation material on a semiconductor layer,
providing an insulation substrate comprising a dielectric material,
connecting a surface region of the base substrate arranged on the insulation material to the insulation substrate by means of a bonding process, and
backthinning the base substrate by removing the semiconductor layer to the insulation material of the base substrate,
wherein the electrode structure for the ion trap is formed by performing the step of backthinning to the metallization arrangement, or by depositing a patterned surface metallization on the insulation material of the back-thinned base substrate,
or
wherein the electrode structure for the ion trap is formed by the patterned metallization arrangement.

2. The method according to claim 1, wherein the metallization arrangement is configured as a multilayer metallization arrangement, wherein the electrode structure for the ion trap is formed by performing the step of backthinning to an uppermost patterned metallization layer of the multilayer metallization arrangement.

3. The method according to claim 1, further comprising:
performing the bonding process between the insulation material of the base substrate and the insulation substrate by means of an oxide/oxide bonding process.

4. The method according to claim 1, wherein the surface region of the base substrate arranged on the insulation material, and the insulation substrate each comprise associated metal pads, further comprising:
performing the bonding process between the base substrate and the insulation substrate at the associated metal pads by means of a metal bonding process.

5. The method according to claim 1, wherein the bonding process is performed as a combination (hybrid bonding process) of an oxide/oxide bonding process and a metal bonding process.

6. The method according to claim 1, wherein the exposed metallization layer of the metallization arrangement or the deposited patterned surface metallization on the insulation material of the back-thinned base substrate forms the electrode structure for the surface ion trap.

7. The method according to claim 1, further comprising:
forming a recess in the form of a hole or trench in the base substrate through the insulation material of the metallization arrangement to the semiconductor layer.

8. The method according to claim 7, wherein the step of forming a recess is performed by means of hole or trench etching.

9. The method according to claim 7, further comprising:
arranging a metallization partially or completely on side walls of the recess in the insulation material of the back-thinned base substrate.

10. The method according to claim 1, wherein the semiconductor layer of the base substrate is completely removed in the step of backthinning the base substrate.

11. The method according to claim 1, wherein the metallization arrangement embedded in the insulation material is configured as an antenna structure for providing electric fields for the ion trap.

12. The method according to any claim 1, wherein the base substrate is configured as a standard substrate from semiconductor manufacturing or as an IC substrate.

13. The method according to any claim 1, wherein the dielectric material of the insulation substrate comprises glass, diamond, sapphire, corundum or ceramic.

14. The method according to claim 1, wherein the insulation material of the base substrate comprises a dielectric from semiconductor manufacturing, such as SiO₂ or HfO₂.

15. The method according to claim 1, wherein the method for manufacturing an electrode structure for an ion trap is performed by means of standard semiconductor manufacturing process steps.

16. The method according to claim 1, wherein the ion trap is provided for quantum computing applications.

17. The method for manufacturing an electrode arrangement for a 3-dimensional ion trap, comprising:
performing the method according to claim 1 for manufacturing an electrode structure on a back-thinned base substrate,
providing a further substrate with a further electrode structure,
connecting the back-thinned base substrate and the further substrate by means of a spacer structure arranged therebetween, so that the electrode structure and the further electrode structure face each other and form the electrode arrangement for the 3-dimensional ion trap.

18. The method according to claim 17, wherein providing the further substrate comprises performing the method according to claim 1 to manufacture a further back-thinned base substrate with an electrode structure forming the further electrode structure, wherein connecting the back-thinned base substrate and the further substrate is performed on the further back-thinned base substrate.

19. The method according to claim 17, wherein in the step of connecting the back-thinned base substrate and the further substrate, two laterally adjacent electrode structures of the back-thinned base substrate are arranged vertically opposite to two laterally adjacent electrode structures of the further substrate.

20. The method according to claim 19, wherein the two vertically opposite pairs of the electrode structures form the controllable electrode arrangement of the 3D ion trap (for quantum computing applications).

21. The method according to claim 17, further comprising:
arranging an interconnect structure on the back-thinned base substrate and a further interconnect structure on the further substrate; and
connecting the back-thinned base substrate and the further substrate by connecting the opposing interconnect structures, wherein the connected interconnect structures form the spacer structure.

22. The method according to claim 17, wherein in the step of connecting the back-thinned base substrate and the further substrate, the spacer structure is configured as a spacer substrate and is arranged between the back-thinned base substrate and the further substrate.

23. The method according to claim 17, wherein the spacer structure comprises a dielectric material, such as glass, diamond, sapphire, corundum or ceramic.

24. The method according to claim 17, wherein the base substrate is fixed on a carrier substrate, e.g., made of a dielectric material such as glass, diamond, sapphire, corundum or ceramic, during the steps of connecting to the insulation substrate, backthinning the base substrate and connecting to the further substrate.

25. The method according to claim 17, further comprising:
patterning the electrode structure of the back-thinned base substrate and/or of the further substrate, for example by means of grey tone lithography, in order to acquire a three-dimensionally patterned electrode structure of the electrode arrangement.

26. The method according to claim 17, wherein in the step of connecting the back-thinned base substrate and the opposing further substrate, a free space is formed between adjacent spacer structures, further comprising:
arranging a metallization surface partially or completely on non-metallic side wall regions of the free space.

27. The method according to claim 17, further comprising providing a metal connection electrically connecting at least a part of the further electrode structure of the further substrate to at least a part of the electrode structure of the back-thinned base substrate.
